(19) United States
(12) Patent Application Publication
(10) Pub. No.: US 2022/0185677 A1
(43) Pub. Date: Jun. 16, 2022

(54) HAFNIUM CARBIDE POWDER FOR PLASMA ELECTRODES, METHOD FOR PRODUCING SAME, HAFNIUM CARBIDE SINTERED BODY, AND PLASMA ELECTRODE

(71) Applicants: CHUBU ELECTRIC POWER CO., INC., Aichi (JP); NISSAN TANAKA CORPORATION, Saitama (JP)

(72) Inventors: Daisuke Ihara, Iruma-gun, Saitama (JP); Yoshimi Sano, Iruma-gun, Saitama (JP); Hirohumi Yoshimoto, Toyonaka-shi (JP); Hideaki Shimizu, Toyonaka-shi (JP); Hideaki Hashimoto, Nagoya-shi (JP); Akihiro Takeuchi, Nagoya-shi (JP); Kiyofumi Higashimoto, Nagoya-shi (JP)

(21) Appl. No.: 17/603,075

(22) PCT Filed: Apr. 15, 2019
(86) PCT No.: PCT/JP2019/016160

§ 371 Date: Oct. 12, 2021

(51) Int. Cl. C01B 32/914; H05H 1/34; C04B 35/56

(52) U.S. Cl. CPC C01B 32/914; H05H 1/34; C01P 2006/80; C01P 2004/61; C04B 2235/786; C04B 35/56

(57) ABSTRACT

Hafnium carbide powder for plasma electrodes is represented by a chemical formula HfCₓ (where x=0.5 to 1.0). The content of carbon particles contained as impurities in the hafnium carbide powder is less than or equal to 0.03% by mass. The hafnium carbide powder preferably has an average particle size of 0.5 to 2 μm. To produce the hafnium carbide powder, a pellet made from mixed powder of hafnium oxide and carbon is first placed in a second crucible made of silicon carbide. Then, the hafnium carbide powder is formed by heating the second crucible at 1800 to 2000° C. with the second crucible arranged in a first crucible made of carbon.

### TECHNICAL FIELD

The present invention relates to hafnium carbide powder for plasma electrodes, a method for producing the same, a hafnium carbide sintered body, and a plasma electrode. The hafnium carbide powder is used as a material for plasma electrodes of plasma torches, for example, and mixing of carbon particles as impurities in the hafnium carbide powder is reduced.

### BACKGROUND ART

A carbothermic reduction method is generally known as a method for producing powder of a compound such as hafnium carbide. The carbothermic reduction method heats metal oxide powder and carbon black to a high temperature in an atmosphere of inert gas to cause a reduction reaction.

For example, Patent Document 1 describes a method of preparing aluminum nitride powder by a carbothermic reduction method. In this preparation method, aluminum oxide powder and carbon black are mixed, and a reduction reaction occurs at a temperature higher than 1600° C. The carbothermic reduction method produces aluminum nitride powder with a high purity, small particle size, and stable functions through a simple preparation process. To produce hafnium carbide powder by the carbothermic reduction method, mixed powder of hafnium oxide (HfO₂) and carbon black (C) is heated to a high temperature of about 2000° C. in an argon atmosphere. The heating causes a reduction reaction, forming power of hafnium carbide (HfC). Since the reduction reaction occurs at a high temperature of 2000° C., this preparation method uses a carbon crucible for heat treatment, and the crucible is covered with carbon powder as a heat insulator. As such, carbon particles of sizes of several μm to several tens of μm tend to be mixed in the hafnium carbide powder when the produced hafnium carbide powder is collected from the crucible. The carbon particles mixed into the hafnium carbide powder are impurities, which lower the quality of the hafnium carbide powder. This lowers the quality of the plasma electrode formed from a sintered body of the hafnium carbide powder, resulting in a shorter life of the plasma electrode.

### PRIOR ART DOCUMENT

### Patent Document

Patent Document 1: Japanese Laid-Open Patent Publication No. 2016-164112

### SUMMARY OF THE INVENTION

### Problems that the Invention is to Solve

It is an objective of the present invention to provide hafnium carbide powder for plasma electrodes that has a quality improved by reducing the mixing of carbon particles as impurities into the hafnium carbide powder, a method for producing the same, a hafnium carbide sintered body, and a plasma electrode.

### Means for Solving the Problems

To achieve the foregoing objective, hafnium carbide powder for plasma electrodes is provided. The hafnium carbide powder is represented by a chemical formula HfCₓ (where x=0.5 to 1.0). A content of carbon particles contained as impurities in the hafnium carbide powder is less than or equal to 0.03% by mass.

### BRIEF DESCRIPTION OF THE DRAWINGS

FIG. 1 is a cross-sectional view schematically showing production equipment used for a first method for producing hafnium carbide powder.

FIG. 2 is a cross-sectional view schematically showing production equipment used for a first heat treatment in a second method for producing hafnium carbide powder.

FIG. 3 is a cross-sectional view schematically showing production equipment used for a second heat treatment in the second method for producing hafnium carbide powder.

FIG. 4A is a schematic plan view showing a planetary ball mill for a milling process.

FIG. 4B is a transverse cross-sectional view showing a pot containing balls and raw materials.

FIG. 4C is a vertical cross-sectional view showing the pot containing the balls and the raw materials.

FIG. 5A is a schematic perspective view showing a sintering mold used in a pulsed electric current sintering apparatus.

FIG. 5B is a diagram illustrating the pulsed electric current sintering apparatus.

FIG. 6A is a schematic cross-sectional view showing a plasma cutting apparatus (plasma cutting torch).

FIG. 6B is a cross-sectional view showing a plasma electrode.

FIG. 7A is a graph showing the relationship between the arc time (min) and the electrode consumption depth (mm) of Example 1 that was not subjected to a milling process.

FIG. 7B is a graph showing the relationship between the arc time (min) and the electrode consumption depth (mm) of Example 1 that was subjected to a milling process.

FIG. 8A is a graph showing the relationship between the arc time (min) and the electrode consumption mass (mg) of Example 1 that was not subjected to a milling process.

FIG. 8B is a graph showing the relationship between the arc time (min) and the electrode consumption mass (mg) of Example 1 that was subjected to a milling process.

FIG. 9A is a graph showing the relationship between the arc time (min) and the electrode consumption depth (mm) of Comparative Example 1.

FIG. 9B is a graph showing the relationship between the arc time (min) and the electrode consumption mass (mg) of Comparative Example 1.

FIG. 10A is a graph showing the relationship between the arc time (min) and the electrode consumption depth (mm) of Comparative Example 2.

FIG. 10B is a graph showing the relationship between the arc time (min) and the electrode consumption mass (mg) of Comparative Example 2.

### MODES FOR CARRYING OUT THE INVENTION

Referring to drawings, embodiments of the present invention are now described in detail.

The hafnium carbide powder of the present embodiment is used as a material for the electrode tip of a plasma electrode. The hafnium carbide powder is represented by the chemical formula HfCₓ (where x=0.5 to 1.0). The content of carbon particles (free carbon) contained as impurities in the hafnium carbide powder is less than or equal to 0.03% by mass. Hafnium carbide is obtained by reducing hafnium oxide (HfO₂) with carbon (C) according to the following Reaction Formula (1). When the carbon content (atomic weight) is greater than or equal to 3, a greater amount of carbon particles remain. When the carbon content (atomic weight) is less than 2, unreduced hafnium oxide remains. As such, the ratio of the molecular weight (atomic weight) of carbon to hafnium oxide is preferably 2 to 3.

HfO₂+3C→HfC+2CO⬆ (1)

The electrode tip of a plasma electrode is formed from a sintered body obtained by sintering hafnium carbide powder. It is desirable that the hafnium carbide powder have fewer impurities and a high purity. However, in the production process, carbon particles having particle sizes of about 5 to 50 μm are mixed as impurities into the hafnium carbide powder. As a result, the content of carbon particles contained as impurities in the hafnium carbide powder is less than or equal to 0.03% by mass. When the content of carbon particles exceeds 0.03% by mass, the qualities of the sintered bodies of the hafnium carbide powder and the plasma electrodes obtained from the sintered bodies vary. This also lowers the durability of the plasma electrode, shortening the life of the plasma electrode.

The average particle size of the hafnium carbide powder is preferably 0.5 to 2 μm, and more preferably 0.5 to 1 μm. When the average particle size is less than 0.5 μm, it is difficult to prepare such fine hafnium carbide powder. This may complicate the production process or lengthen the production time. When the average particle size is greater than 2 μm, the variation of the hafnium carbide powder particles becomes greater, and some of the particles are excessively large. Thus, a homogeneous sintered body is unlikely to be obtained.

A first production method and a second production method are now described as methods for producing hafnium carbide powder for plasma electrodes.

First, the first production method is described.

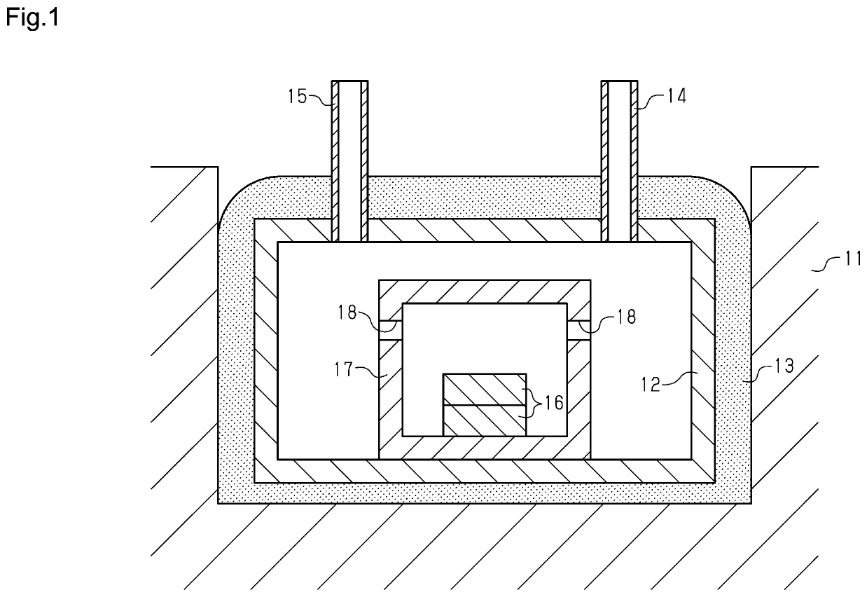

As shown in FIG. 1, a first crucible 12 made of carbon is arranged in a high-frequency induction heating furnace 11. The space between the first crucible 12 and the inner surface of the high-frequency induction heating furnace 11 is filled with carbon (C) powder 13 as a heat insulator to cover the first crucible 12. The upper wall of the first crucible 12 is connected to a supply pipe 14, through which argon gas is introduced as an inert gas, and a discharge pipe 15 for discharging a gas such as carbon monoxide (CO) generated in the first crucible 12.

A second crucible 17 made of silicon carbide (SiC) is arranged in the first crucible 12. The second crucible 17 contains pellets 16 made from mixed powder of hafnium oxide (HfO₂) and carbon (C), which are raw materials. The side wall of the second crucible 17 has vent holes 18, which open to introduce argon gas and discharge gas such as carbon monoxide.

In the first method for producing hafnium carbide powder, the pellets 16 are placed in the second crucible 17, and then the second crucible 17 is arranged in the first crucible 12. Subsequently, argon gas is supplied into the first crucible 12 through the supply pipe 14, so that the first crucible 12 is filled with the argon gas. The argon gas enters the second crucible 17 through the vent holes 18, so that the second crucible 17 is also filled with the argon gas.

In this state, the high-frequency induction heating furnace 11 is activated to heat the inside of the high-frequency induction heating furnace 11 to 1800 to 2000° C. As a result, reduction and carbonization reactions of hafnium oxide occur in the second crucible 17 according to Reaction Formula (1), thereby forming hafnium carbide powder.

At this time, the gas generated as a by-product, such as carbon monoxide (CO) gas, is discharged to the outside through the vent holes 18 of the second crucible 17, the first crucible 12, and the discharge pipe 15. After completion of the reaction, the second crucible 17 is removed from the first crucible 12, and then the hafnium carbide powder is collected from the second crucible 17.

The obtained hafnium carbide powder is subjected to a milling process (grinding process) to adjust the particle size of the hafnium carbide powder. The milling process is now described.

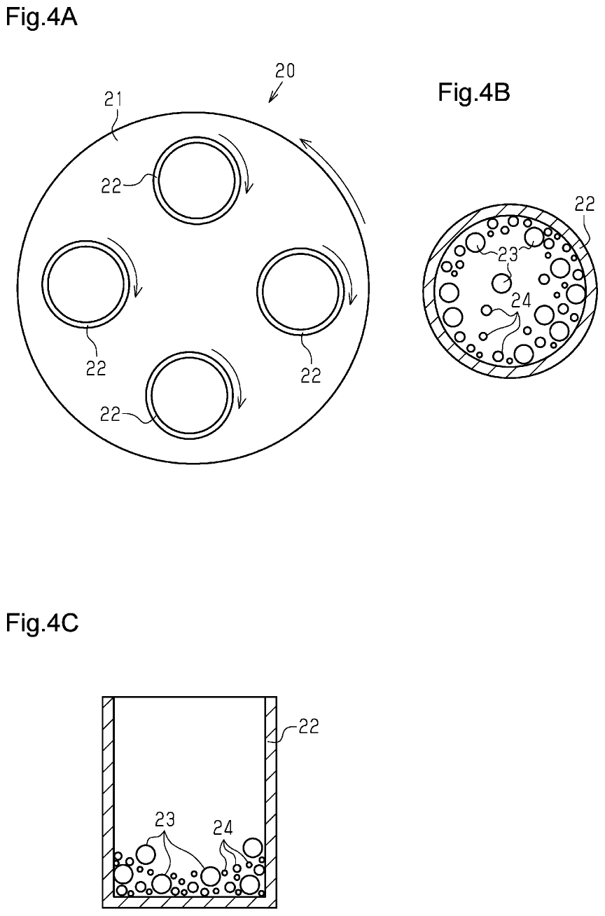

As shown in FIG. 4A, a disk-shaped revolving member 21 forming a planetary ball mill 20 for a milling process revolves in the counterclockwise direction shown by an arrow in FIG. 4A, for example. Four cylindrical pots 22, each having one closed end, are arranged in the revolving member 21. The four pots 22 are arranged at intervals of 90 degrees in the circumferential direction of the revolving member 21. The pots 22 rotate in the clockwise direction indicated by arrows in FIG. 4A, for example. The revolving direction of the revolving member 21 and the rotation direction of the pots 22 can be arbitrarily set.

As shown in FIGS. 4B and 4C, each pot 22 contains balls 23 for grinding and hafnium carbide powder 24 of different particle sizes. In this state, the revolving member 21 is revolved, and the pots 22 are rotated. The revolution and the rotation create a strong centrifugal force acting on the balls 23 and the hafnium carbide powder 24. The collision energy of the balls 23 applies a compressing force and a shearing force on the hafnium carbide powder 24. As a result, the hafnium carbide powder 24 is ground and pulverized. Additionally, the hafnium carbide powder 24 is homogenized.

The second method for producing hafnium carbide powder is now described. The second production method includes a first heat treatment with a first heat treatment apparatus and a second heat treatment with a second heat treatment apparatus.

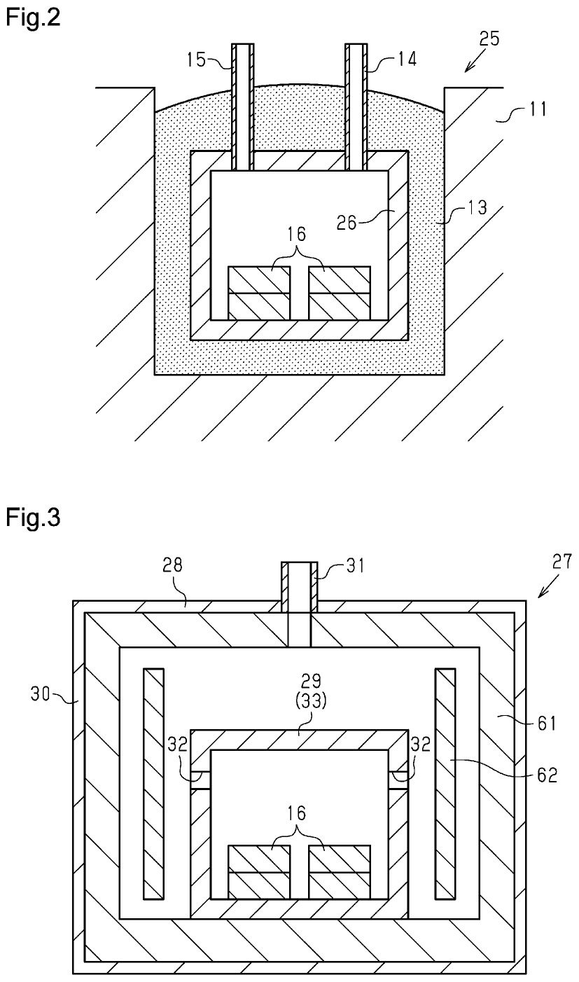

As shown in FIG. 2, a third crucible 26, which is made of carbon and contains pellets 16, is arranged in a high-frequency induction heating furnace 11 serving as the first heat treatment apparatus 25. The third crucible 26 is connected to a supply pipe 14, through which an inert gas such as argon gas is introduced, and a discharge pipe 15 for discharging a gas such as carbon monoxide gas. The space between the third crucible 26 and the inner surface of the high-frequency induction heating furnace 11 is filled with carbon powder 13 as a heat insulator to cover the third crucible 26.

With the pellets 16 contained in the third crucible 26, an inert gas is supplied into the third crucible 26 through the supply pipe 14, so that the third crucible 26 is filled with the inert gas. In this state, the high-frequency induction heating furnace 11 is activated to heat the inside of the third crucible 26 to 1800 to 2000° C., thus performing the first heat treatment. As a result, reduction and carbonization reactions of hafnium oxide occur according to Reaction Formula (1), thereby forming hafnium carbide powder 24.

As shown in FIG. 3, a fourth crucible 29 made of silicon carbide or a fifth crucible 33 made of carbon, which contains pellets 16, is arranged in a vacuum container 30 of a vacuum heating furnace 28 serving as the second heat treatment apparatus 27. A vacuum suction pipe 31 is connected to the vacuum container 30. The inside of the vacuum container 30 is depressurized to a predetermined degree of vacuum. A heat insulator 61 is arranged on the inner surface of the vacuum container 30. A heater 62 is arranged in the inner space of the vacuum container 30. Connecting holes 32 open in the fourth crucible 29 or the fifth crucible 33. This allows the fourth crucible 29 or the fifth crucible 33 to have the same degree of vacuum as the vacuum heating furnace 28.

After the first heat treatment, the third crucible 26 is removed from the high-frequency induction heating furnace 11, and the pellets 16 (hafnium carbide powder 24) are collected from the third crucible 26. The collected pellets 16 (hafnium carbide powder 24) are subjected to component analysis. If a large amount of unreacted hafnium oxide remains, fine particles of carbon may be added.

The obtained pellets 16 are placed in the fourth crucible 29 or the fifth crucible 33, which is then arranged in the vacuum heating furnace 28. The air in the vacuum heating furnace 28 is then drawn out through the vacuum suction pipe 31 to set the inside of the vacuum heating furnace 28 to a predetermined degree of vacuum. At this time, the air in the fourth crucible 29 or the fifth crucible 33 is also drawn out through the connecting holes 32 of the fourth crucible 29 or the fifth crucible 33. This allows the fourth crucible 29 or the fifth crucible 33 to have the same degree of vacuum as the vacuum heating furnace 28. In this state, the inside of the vacuum heating furnace 28 and the inside of the fourth crucible 29 or the fifth crucible 33 are heated to 1800 to 2000° C., thus performing the second heat treatment. This further facilitates the reduction and carbonization reactions of hafnium oxide, reducing the carbon particles in the hafnium carbide powder 24.

The obtained hafnium carbide powder 24 is subjected to a milling process in the same manner as in the first production method, so that the hafnium carbide powder 24 is ground, pulverized, and homogenized.

The sintering of the hafnium carbide powder 24 is now described.

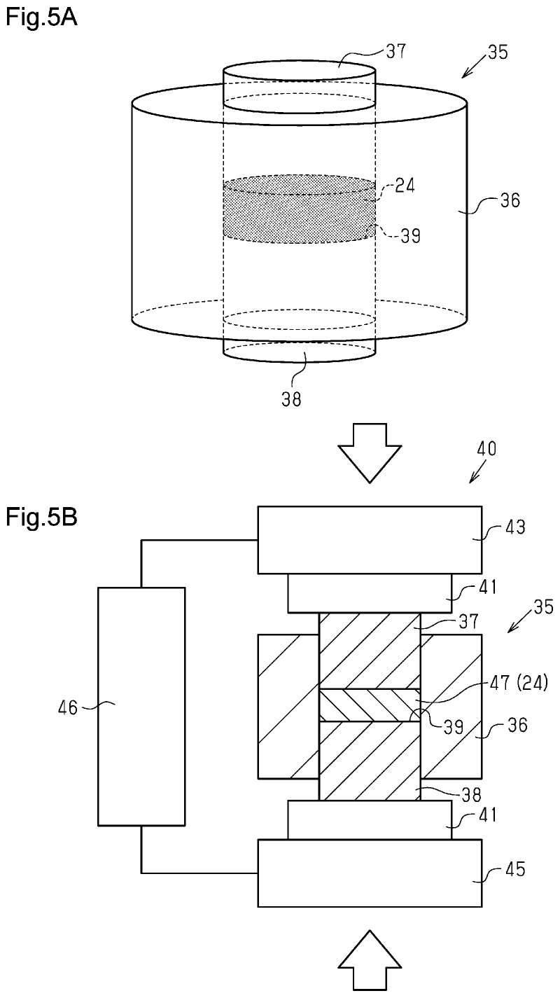

As shown in FIG. 5A, a cylindrical die 36, which forms a sintering mold 35 (die), defines an inner space. An upper punch 37 is fitted in the upper part of the inner space, and a lower punch 38 is fitted in the lower part. A sample loading section 39 is provided between the upper punch 37 and the lower punch 38. The sample loading section 39 is filled with the hafnium carbide powder 24 that has been subjected to the milling process.

As shown in FIG. 5B, an upper electrode 43 is arranged above the upper punch 37 of the sintering mold 35, which forms a pulsed electric current sintering apparatus 40, through a spacer 41. A lower electrode 45 is arranged below the lower punch 38 through a spacer 41. A pulsed power supply 46 is connected between the upper electrode 43 and the lower electrode 45, and a pulsed current is applied between the upper electrode 43 and the lower electrode 45. As indicated by the arrows in FIG. 5B, a pulsed current is applied between the upper electrode 43 and the lower electrode 45 with the upper electrode 43 and the lower electrode 45 pressed from above and below. The hafnium carbide powder 24 is thus heated and sintered by Joule heat to form a sintered body 47.

A plasma electrode formed from the sintered body 47 of the hafnium carbide powder 24 is now described.

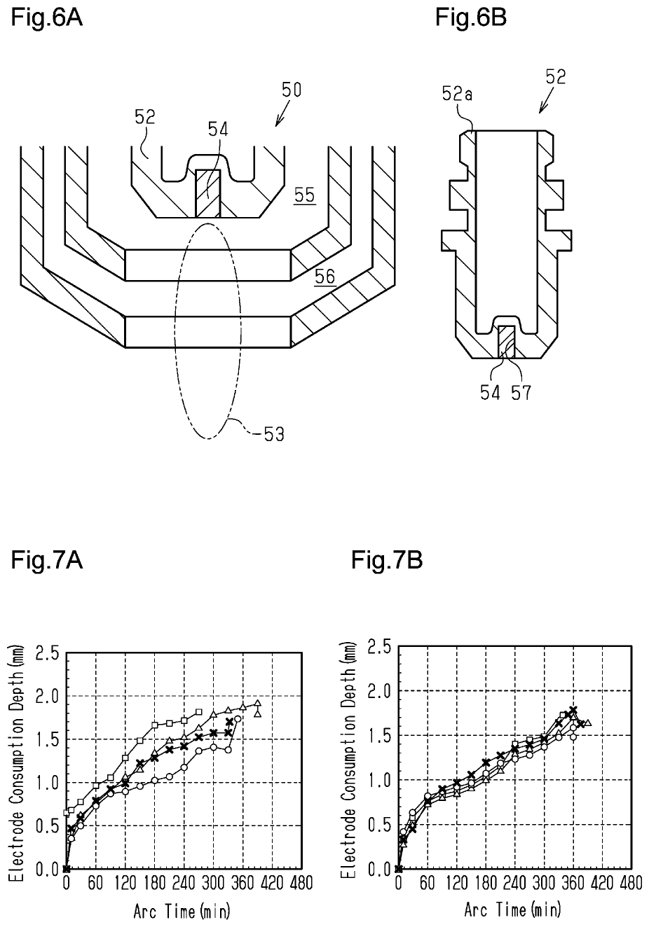

As shown in FIG. 6A, a plasma electrode 52 having a substantially cylindrical shape is attached to the end portion of a plasma cutting torch 50. An electrode tip 54 for emitting a plasma arc 53 is fitted in the end section of the plasma electrode 52. A plasma gas passage 55 for injecting plasma gas is provided on the outer circumference of the plasma electrode 52. Also, an assist gas passage 56 for injecting an assist gas such as nitrogen gas is provided on the outer circumference of the plasma gas passage 55.

As shown in FIG. 6B, a cylindrical mounting hole 57 is provided in the distal end portion of an electrode main body 52a forming the plasma electrode 52. The electrode tip 54 is fitted in the mounting hole 57. The electrode main body 52a is formed by cutting a copper rod. The electrode tip 54 is formed from a bulk material of the sintered body 47 of hafnium carbide powder 24 by electric discharge machining and grinding. The electrode tip 54 is fitted into the mounting hole 57 of the electrode main body 52a and brazed. Then, the section of the electrode main body 52a extending beyond the tip surface is ground to form the plasma electrode 52.

An operation of the hafnium carbide powder 24 of the present embodiment and the method for producing the same is now described.

The above-mentioned first production method and the second production method may be used to produce the hafnium carbide powder 24. The first production method arranges the second crucible 17 in the first crucible 12 and produces the hafnium carbide powder 24 in the second crucible 17. This allows the hafnium carbide powder 24 to be collected from the second crucible 17 after the sealed second crucible 17 is removed from the high-frequency induction heating furnace 11. As such, the carbon first crucible 12 or the carbon powder 13 serving as the heat insulator does not affect the hafnium carbide powder 24, so that carbon particles are not mixed into the hafnium carbide powder 24.

The second production method performs the first heat treatment, which is a conventional process, in the third crucible 26 in the high-frequency induction heating furnace 11, then takes the hafnium carbide powder 24 out from the third crucible 26, and transfers it to the fourth crucible 29 of the fifth crucible 33. The fourth crucible 29 or the fifth crucible 33 is then arranged in the vacuum heating furnace 28 to perform the second heat treatment. Accordingly, the carbon particles mixed in the hafnium carbide powder 24 in the first heat treatment are consumed by the reduction and carbonization reactions of hafnium oxide in the second heat treatment. This reduces the content of carbon particles in the hafnium carbide powder 24.

As a result, the content of carbon particles contained as impurities in the hafnium carbide powder 24 does not exceed 0.03% by mass. The quality of the sintered body 47 obtained by sintering the hafnium carbide powder 24 is therefore improved. This limits the cracking of an electrode tip 54 of the plasma electrode 52 formed from the sintered body 47, which would otherwise be caused by carbon particles. Consequently, the plasma electrode 52 has a longer life.

The advantages of the above-described embodiment are listed below.

(1) The hafnium carbide powder 24 for the plasma electrode 52 is represented by the chemical formula HfCₓ (where x=0.5 to 1.0). The content of carbon particles contained as impurities in the hafnium carbide powder 24 is less than or equal to 0.03% by mass. As such, the mixing of carbon particles as impurities is reduced with the hafnium carbide powder 24 of the present embodiment, improving the quality of the hafnium carbide powder 24.

(2) The average particle size of the hafnium carbide powder 24 is 0.5 to 2 μm. Accordingly, the particles of the hafnium carbide powder 24 are fine, have a narrow particle size distribution, and are homogeneous. A dense sintered body 47 can therefore be obtained from the hafnium carbide powder 24.

(3) In the first method for producing hafnium carbide powder, the pellets 16 made of mixed powder of hafnium oxide and carbon are placed in the second crucible 17 made of silicon carbide. Then, the second crucible 17 is arranged in the first crucible 12 made of carbon, and a heating reaction occurs at 1800 to 2000° C. to form the hafnium carbide powder 24. The hafnium carbide powder 24 is thus formed in the second crucible 17 arranged in the first crucible 12. Since the hafnium carbide powder 24 is collected after the second crucible 17 is removed from the first crucible 12, the mixing of impurities into the hafnium carbide powder 24 is avoided.

(4) In the second method for producing the hafnium carbide powder 24, the pellets 16 are first placed in the third crucible 26, which is made of carbon, for the first heat treatment. Then, the third crucible 26 is arranged in the high-frequency induction heating furnace 11, and the high-frequency induction heating furnace 11 is filled with carbon powder 13. In this state, an inert gas is supplied into the third crucible 26, and a heating reaction is caused at 1800 to 2000° C. with the third crucible 26 filled with the inert gas. Subsequently, the obtained hafnium carbide powder 24 is transferred to the fourth crucible 29 or the fifth crucible 33. Then, the inside of the vacuum heating furnace 28 and the inside of the fourth crucible 29 or the fifth crucible 33 are evacuated. In this state, the hafnium carbide powder 24 is formed by performing the second heat treatment at 1800 to 2000° C. In this manner, the carbon particles contained as impurities in the hafnium carbide powder 24 obtained in the first heat treatment undergo a reaction in the second heat treatment and are thus minimized.

(5) The formed hafnium carbide powder 24 is subjected to a milling process to adjust the particle size of the hafnium carbide powder 24. The milling process achieves the fine-grained, homogenized hafnium carbide powder 24.

(6) The sintered body 47 of the hafnium carbide powder 24 is obtained by heating and sintering the hafnium carbide powder 24 with the pulsed electric current sintering apparatus 40. The sintered body 47 is thus easily obtained from the hafnium carbide powder 24. Moreover, in accordance with the characteristics of the hafnium carbide powder 24, the sintered body 47 has fewer impurities and is homogeneous.

(7) The plasma electrode 52 is formed from the sintered body 47 of the hafnium carbide powder 24. The plasma electrode 52 thus has a stable quality and a longer life.

### EXAMPLES

Examples and comparative examples are now described to further illustrate the details of the embodiments described above.

### Example 1

In Example 1, hafnium carbide powder 24 was produced by the first production method described above.

First, the raw materials of the hafnium carbide powder 24, which were hafnium oxide powder having an average particle size of 1 μm or less and carbon black powder having an average particle size of 0.1 μm or less, were wet mixed and then dried. The dried mixed material was ground to obtain an aggregate having a particle size of 3 mm or less. The aggregate was pressed and shaped into a columnar pellet 16 with a diameter of 75 mm.

The obtained pellet 16 was placed in the second crucible 17, and the second crucible 17 was arranged in the first crucible 12. Then, argon gas was supplied into the first crucible 12 through the supply pipe 14. In this state, the high-frequency induction heating furnace 11 was activated to heat the inside of the second crucible 17 to 1800 to 2000° C., thereby causing reduction and carbonization reactions of the hafnium oxide. The average particle size of the hafnium carbide powder 24 thus obtained was 0.72 μm. The content of carbon particles contained as impurities in the hafnium carbide powder 24 was 0.01% by mass. The particle sizes of the carbon particles were 5 to 10 μm.

The obtained hafnium carbide powder 24 was milled for 4 hours by a dry milling method using the planetary ball mill 20.

After the milling process, the hafnium carbide powder 24 was heated to 1800 to 1900° C. and sintered under a pressure of 70 to 90 MPa using the pulsed electric current sintering apparatus 40. In this manner, a sintered body 47 having a diameter of 30 mm and a length of 6 mm was prepared. The sintered body 47 was subjected to electric discharge machining to obtain an electrode tip 54 for a plasma electrode 52 having a diameter of 2 mm and a length of 6 mm. The electrode tip 54 was then joined to the distal end of the electrode main body 52a by silver brazing to produce a plasma electrode 52.

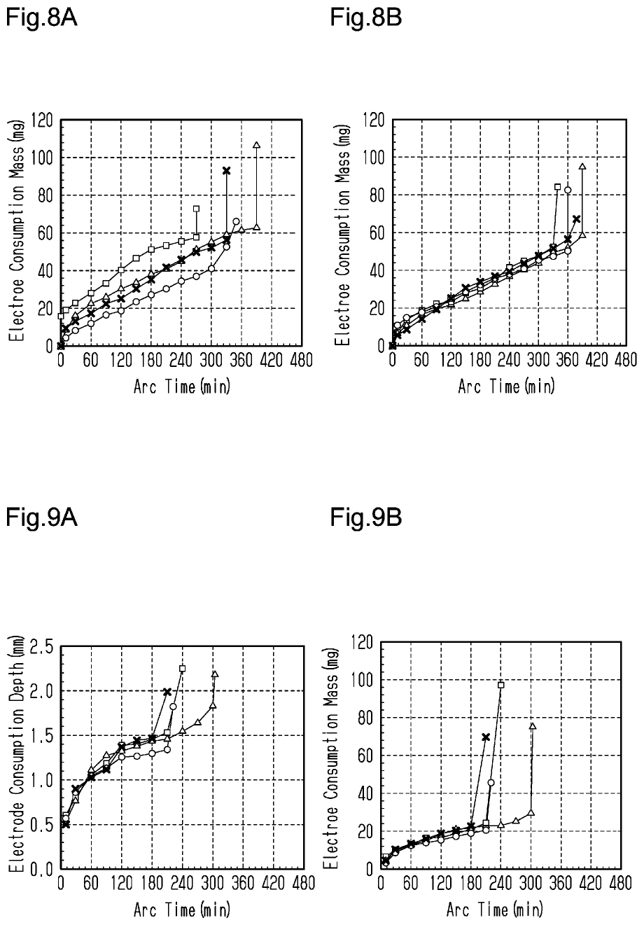

Under the condition of a current of 300 A, the relationship between the arc time (min) of the plasma arc 53 and the electrode consumption depth (mm), and the relationship between the arc time (min) of the plasma arc 53 and the electrode consumption mass (mg) were obtained with the produced plasma electrode 52. FIGS. 7A to 8B show the relationships. FIGS. 7A and 8A show examples in which the hafnium carbide powder 24 was not subjected to a milling process. FIGS. 7B and 8B show examples in which the hafnium carbide powder 24 was subjected to a milling process. In each figure, □, Δ, and × represent the results of three samples with sintering conditions of 1850° C. and 80 MPa, and ∘ represents a sample with sintering conditions of 1900° C. and 70 MPa.

As shown in FIGS. 7A to 8B, each plasma electrode 52 obtained using the hafnium carbide powder 24 of Example 1 had a long life regardless of whether the hafnium carbide powder 24 was milled. Furthermore, the results indicate that the samples with a milling process have smaller differences between the samples and were more homogeneous than the samples without a milling process.

### Comparison Example 1

In Comparative Example 1, hafnium carbide powder 24 was produced by a conventional method. That is, the hafnium carbide powder 24 was produced by the first heat treatment in the second production method.

As shown in FIG. 2, pellets 16 of Example 1 were placed in the third crucible 26 made of carbon, the third crucible 26 was arranged in the high-frequency induction heating furnace 11, and the space between the third crucible 26 and the inner surface of the high-frequency induction heating furnace 11 was filled with carbon powder 13 as a heat insulator. The high-frequency induction heating furnace 11 was activated to heat the inside of the third crucible 26 to 1800 to 2000° C., thereby causing reduction and carbonization reactions of the hafnium oxide.

The average particle size of the hafnium carbide powder 24 thus obtained was 0.71 μm. The content of carbon particles contained as impurities in the hafnium carbide powder 24 was 0.06% by mass. The particle sizes of the carbon particles varied in a wide range between 5 and 50 μm, inclusive.

In the same manner as in Example 1, the hafnium carbide powder 24 was milled by the dry milling method using the planetary ball mill 20. Also, the hafnium carbide powder 24 was heated and sintered with the pulsed electric current sintering apparatus 40 to obtain a cylindrical sintered body 47 having a diameter of 30 mm in the same manner as in Example 1. An electrode tip 54 was obtained through electric discharge machining of the sintered body 47, and a plasma electrode 52 was produced using the electrode tip 54.

Under the condition of a current of 150 A, the relationship between the arc time (min) of the plasma arc 53 and the electrode consumption depth (mm), and the relationship between the arc time (min) of the plasma arc 53 and the electrode consumption mass (mg) were obtained with the produced plasma electrode 52. FIGS. 9A and 9B show the relationships. In each figure, □, Δ, ∘ and × indicate the results of four samples with the same conditions.

As shown in FIGS. 9A and 9B, even though the current was 150 A (half of the 300 A that was used in Example 1), the plasma electrodes 52 obtained by using the hafnium carbide powder 24 of Comparative Example 1 had arc times of 180 to 300 min, and the consumption depth and the consumption mass increased rapidly. This indicates that the life of the plasma electrode 52 of Comparative Example 1 is clearly shorter than the life of the plasma electrode 52 of Example 1.

### Example 2

In Example 2, hafnium carbide powder 24 was produced by the second production method described above. The pellet 16, which is the raw material of hafnium carbide powder 24, was prepared in the same manner as in Example 1.

As shown in FIG. 2, the pellet 16 was placed in the third crucible 26 made of carbon, the third crucible 26 was arranged in the high-frequency induction heating furnace 11, and the space between the third crucible 26 and the inner surface of the high-frequency induction heating furnace 11 was filled with carbon powder 13 as a heat insulator. The high-frequency induction heating furnace 11 was then activated to heat the inside of the third crucible 26 to 1800 to 2000° C., thereby performing the first heat treatment. Reduction and carbonization reactions of the hafnium oxide thus occurred and produced hafnium carbide powder 24.

Then, as shown in FIG. 3, the third crucible 26 was removed from the high-frequency induction heating furnace 11, and the hafnium carbide powder 24 was loaded into the fourth crucible 29 made of silicon carbide from the third crucible 26. After the fourth crucible 29 was arranged in the vacuum heating furnace 28, the inside of the vacuum heating furnace 28 was heated to 1800 to 2000° C. under a vacuum of about 10 Pa to perform the second heat treatment. The second heat treatment facilitated the reduction and carbonization reactions of hafnium oxide and reduced the carbon particles remaining as impurities in the hafnium carbide powder 24.

The average particle size of the hafnium carbide powder 24 thus obtained was 1.19 μm. The content of carbon particles contained as impurities in the hafnium carbide powder 24 was 0.02% by mass. The particle size of the carbon particles was 5 to 10 μm.

### Example 3

In Example 3, hafnium carbide powder 24 was prepared in the same manner as in Example 2, except that the second heat treatment was performed by loading the hafnium carbide powder 24 into the fifth crucible 33 made of carbon from the third crucible 26.

As a result, the average particle size of the obtained hafnium carbide powder 24 was 1.02 μm. The content of carbon particles contained as impurities in the hafnium carbide powder 24 was 0.02% by mass. The particle size of the carbon particles was 5 to 10 μm.

### Comparative Example 2

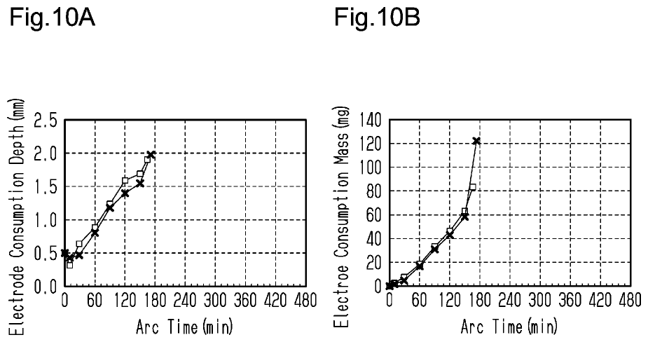

In Comparative Example 2, under the condition of a current of 300 A, the relationship between the arc time (min) of the plasma arc 53 and the electrode consumption depth (mm), and the relationship between the arc time (min) of the plasma arc 53 and the electrode consumption mass (mg) were obtained with conventional metal hafnium electrodes. FIGS. 10A and 10B show the relationships. In each figure, □ indicates the result of sample 1, and × indicates the result of sample 2.

As shown in FIGS. 10A and 10B, the metal hafnium electrode of Comparative Example 2 showed a tendency in which the consumption depth and the consumption mass suddenly increased when the arc time reached 150 min with a current of 300 A. This clearly indicates that the life of the plasma electrode 52 of Comparative Example 2 is shorter than the life of the plasma electrode 52 of Example 1.

The embodiments may be modified as follows.

As the milling process, a process may be employed that uses a vibration ball mill, a wet ball mill, a jet mill, a bead mill, or the like. Furthermore, other processes using an attritor may also be used. The grinding process may include, in addition to the process using the planetary ball mill 20 of the present embodiment, various milling processes described above and other processes using an attritor.

Instead of high-frequency induction heating, a heating method such as microwave heating or electric heating may be used.

The material of the fourth crucible 29 or the fifth crucible 33 may be changed to ceramics such as alumina, magnesia, and zirconia.

1. Hafnium carbide powder for plasma electrodes, wherein
the hafnium carbide powder is represented by a chemical formula HfCₓ (where x=0.5 to 1.0), and
a content of carbon particles contained as impurities in the hafnium carbide powder is less than or equal to 0.03% by mass.

2. The hafnium carbide powder for plasma electrodes according to claim 1, wherein the hafnium carbide powder has an average particle size of 0.5 μm to 2 μm.

3. A method for producing the hafnium carbide powder for plasma electrodes according to claim 1, the method comprising:
placing mixed powder of hafnium oxide and carbon in a crucible made of silicon carbide; and
forming the hafnium carbide powder by heating the silicon carbide crucible at 1800° C. to 2000° C. with the silicon carbide crucible arranged in a crucible made of carbon.

4. A method for producing the hafnium carbide powder for plasma electrodes according to claim 1, the method comprising:
placing mixed powder of hafnium oxide and carbon in a crucible made of carbon;
arranging the carbon crucible in a high-frequency induction heating furnace;
introducing carbon powder into the high-frequency induction heating furnace to cover the carbon crucible;
obtaining the hafnium carbide powder by performing a first heat treatment at 1800° C. to 2000° C. with the carbon crucible filled with an inert gas;
after obtaining the hafnium carbide powder by the first heat treatment, transferring the hafnium carbide powder in the carbon crucible to a different crucible made of silicon carbide or carbon;
placing the different crucible made of silicon carbide or carbon in a vacuum heating furnace; and
forming the hafnium carbide powder by performing a second heat treatment at 1800° C. to 2000° C. with the different crucible made of silicon carbide or carbon evacuated.

5. The method for producing the hafnium carbide powder for plasma electrodes according to claim 3, further comprising performing a grinding process on the formed hafnium carbide powder to adjust a particle size of the hafnium carbide powder.

6. A hafnium carbide sintered body for plasma electrodes, wherein the hafnium carbide sintered body is formed by sintering the hafnium carbide powder according to claim 1.

7. A plasma electrode comprising the hafnium carbide sintered body for plasma electrodes according to claim 6.

8. A method for producing the hafnium carbide powder for plasma electrodes according to claim 2, the method comprising:
placing mixed powder of hafnium oxide and carbon in a crucible made of silicon carbide; and
forming the hafnium carbide powder by heating the silicon carbide crucible at 1800° C. to 2000° C. with the silicon carbide crucible arranged in a crucible made of carbon.

9. A method for producing the hafnium carbide powder for plasma electrodes according to claim 2, the method comprising:
placing mixed powder of hafnium oxide and carbon in a crucible made of carbon;
arranging the carbon crucible in a high-frequency induction heating furnace;
introducing carbon powder into the high-frequency induction heating furnace to cover the carbon crucible;
obtaining the hafnium carbide powder by performing a first heat treatment at 1800° C. to 2000° C. with the carbon crucible filled with an inert gas;
after obtaining the hafnium carbide powder by the first heat treatment, transferring the hafnium carbide powder in the carbon crucible to a different crucible made of silicon carbide or carbon;
placing the different crucible made of silicon carbide or carbon in a vacuum heating furnace; and
forming the hafnium carbide powder by performing a second heat treatment at 1800° C. to 2000° C. with the different crucible made of silicon carbide or carbon evacuated.

10. The method for producing the hafnium carbide powder for plasma electrodes according to claim 4, further comprising performing a grinding process on the formed hafnium carbide powder to adjust a particle size of the hafnium carbide powder.

11. A hafnium carbide sintered body for plasma electrodes, wherein the hafnium carbide sintered body is formed by sintering the hafnium carbide powder according to claim 2.
